(19) United States
(12) Patent Application Publication
(10) Pub. No.: US 2004/0100784 A1
(43) Pub. Date: May 27, 2004

(54) Apparatus and method for grounding EMI/RFI from data/signal cable

(76) Inventors: Arthur G. Willers, Delran, NJ (US); Stanton Kent, Laurel Springs, NJ (US)

Correspondence Address: BAKER + HOSTETLER LLP, WASHINGTON SQUARE, SUITE 1100, 1050 CONNECTICUT AVE. N.W., WASHINGTON, DC, 20036-5304, US

(21) Appl. No.: 10/305,365

(22) Filed: Nov. 27, 2002

(51) Int. Cl. H05K 9/00

(52) U.S. Cl. 361/816

(57) ABSTRACT

Apparatus and method for shielding interference, comprising a clamping bracket filled with a filling member, designed to accommodate cables of varying sizes, allow for easy substitution of one cable for another and provide a means to integrate the faraday cage between multiple chassis/enclosures.

### FIELD OF INVENTION

This invention relates to shielding interference. More specifically, this invention relates to shielding electromagnetic interference (“EMI”) and radio frequency interference (“RFI”) in electronic devices.

### BACKGROUND OF THE INVENTION

EMI, especially RFI (EMI on the radio band), is a potential problem whenever more than one piece of electronic equipment coexist in the same environment. Computer hardware emits electromagnetic waves at frequencies throughout the spectrum. If this EMI is not controlled, a computer or network apparatus can interfere with the use of other devices that transmit or receive electromagnetic radiation, including AM and FM radios, televisions, cellular telephones and other personal communication devices, and medical devices such as pacemakers, hearing aids, and defibrillators. Additionally, within a large computer structure, the individual components can function sub-optimally if EMI is not properly curtailed. For these and other reasons, electromagnetic emissions are regulated, within the United States, by the Federal Communications Commission (FCC). Compliance with FCC rules for acceptable level and frequency of electromagnetic interference is required for any product sold in the United States, and is therefore extremely important to manufacturers and users of devices that emit electromagnetic radiation.

Within the environment of an electronic computer or cabinet, cables are used to transmit data and/or signals from one point to another. Cables can be used to transmit data from storage devices within the computer, from across the world via the Internet, or from anywhere in between. Cables can also be used to transmit signals of one kind or another to different parts of the electronic system, so that those parts can function appropriately.

Problems with EMI can be minimized by ensuring that all equipment that emits electromagnetic radiation is effectively grounded. This is often done by shielding the conductive material in the cable from the external environment, by wrapping the cable with a shielding material. Shielded cable is known in the art. However, often, cable will need to be unshielded in places to function in the system, or when shielding to mask necessary EMI is prohibitive in terms of cost or space.

In larger electronic cabinets, especially in computer and data network equipment, a large number of data and signal cables enter the system through different chassis. These cables have a multitude of sizes, shapes, shielding, and purposes. Various chassis for cable entry into electronic cabinets are known in the art. However, many chassis known in the art that reduce EMI subject the cables to deformation in the form of compression, which can hinder performance of the cable's function.

Additionally, many prior art solutions cannot accommodate cables having various thicknesses, because the shielding material used has a specific opening for a cable. The inability of different types of cables, each having a different thickness, to enter or exit a system, inhibits system growth.

Many cable chassis in the prior art have fixed parts. This makes these chassis difficult to assemble, requiring skilled labor for such assembly, and fixturing. Additionally, these fixed parts limit the choices that consumers of these chassis can make with respect to the type of cable they use.

Chassis known in the art do not permit interconnection with one another. Known chassis cannot adequately function as sub-chassis in a larger structure, because the shielded faraday cage is not maintained with each of the sub-chassis. In a large component of a larger system, a single cable may need to enter through one sub-chassis, and exit through another. In prior art systems, such a cable would not be properly grounded, and EMI would result. In other systems, upgrade ability is prohibitively expensive, making a decision to change cable type prohibitively expensive. The inability to link chassis to each other while maintaining a shielded faraday cage severely limits the expandability of electronic cabinet setups.

### SUMMARY OF THE INVENTION

The foregoing need has been met, to a great extent, by the present invention wherein one aspect, an apparatus capable of reducing interference from a cable within an enclosure is disclosed. The apparatus contains a front panel with a first opening, and a first filling member, attached to the front panel. The filling member shields interference. In one embodiment of this aspect of the present invention, the apparatus contains a clamping bracket, positioned adjacent to the first opening. The clamping bracket has a second opening, which is positioned adjacent to the first opening. The cable is positioned through an opening of the first filling member.

In another aspect of the present invention, a method of limiting interference into or out of an enclosure, which is caused by an opening, is disclosed. The method includes the step of placing a shielding material at the opening. If a shielded cable is passed through the opening, the cable is encased with a shielding material at the opening. The shielding material is grounded to the enclosure. In one embodiment of the present invention, the method further comprises providing a bracket to secure the shielding material at the opening, providing a front panel which is secured and grounded to the enclosure at the opening, with the bracket attached to the front panel, and the bracket secures a plurality of the shielding material.

In another aspect of the present invention, an system for limiting interference in and out of an enclosure, wherein the interference leaks through an opening of the enclosure, is disclosed. The apparatus includes a means for shielding interference at the opening, and a means for grounding shielding material to the enclosure.

In another aspect of the present invention, an apparatus is disclosed. The apparatus contains a cabinet that contains electrical components. The cabinet has a first opening located on a first outer portion, and a second opening located on a second outer portion. The apparatus also contains a first filling member, which shields interference, within the first opening and a second filling member, which shields interference, within the second opening.

There has been outlined, rather broadly, the more important features of the invention in order that the detailed description thereof that follows may be better understood, and in order that the present contribution to the art may be better appreciated. There are, of course, additional features of the invention that will be described below and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein, as well as the abstract, are for the purposes of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent construction insofar as they do not depart from the spirit and scope of the present invention.

### BRIEF DESCRIPTION OF THE DRAWINGS

FIG. 1 is a break apart view of a preferred embodiment of the present invention, illustrating the individual component parts.

FIG. 2 is a perspective view of the present invention.

FIG. 3 is a flow-chart of an alternate embodiment of the present invention.

FIG. 4 is a top view of an implementation of the preferred embodiment of the present invention.

FIG. 5 is a perspective view of the implementation of the preferred embodiment depicted in FIG. 4.

### DETAILED DESCRIPTION OF THE INVENTION

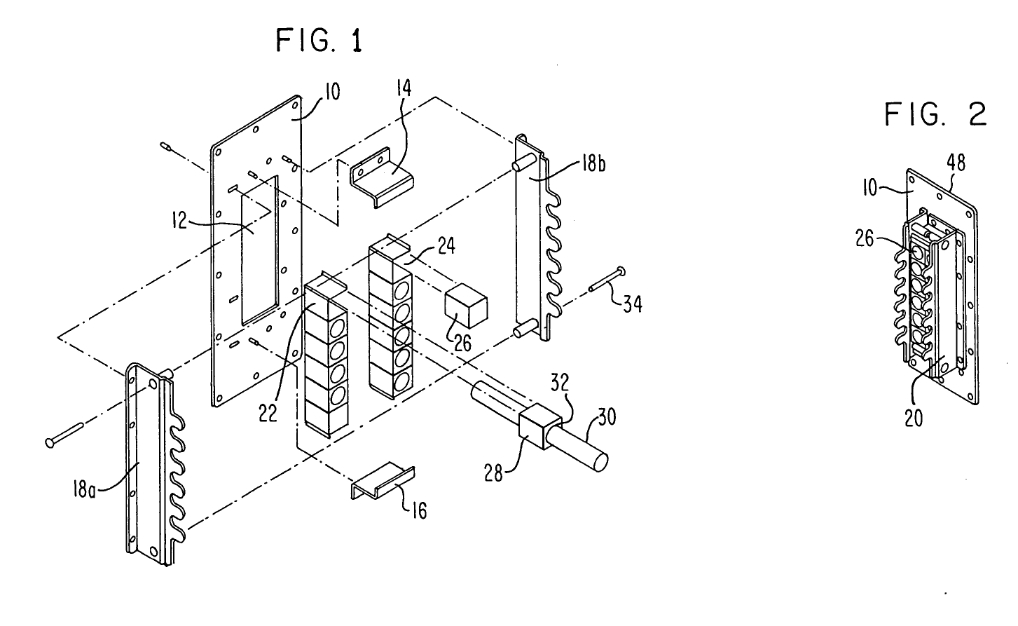

Referring now to FIG. 1, an apparatus for shielding interference from a cable is shown, which is a preferred embodiment of the present invention. A front panel 10 is shown having a first opening 12. An upper bracket 14, a lower bracket 16, and side brackets 18a and 18b make up the outside of the clamping bracket 20. The inside of the clamping bracket 20 is made up of a plurality of angled members 22. The angled members 22 are rectangular in shape, having three sides (not labeled), with the fourth side including an opening. The opening can be on any side of the rectangular structure of the member 22. The angled member 22 does not contain any material within its rectangular structure, and thus there is a second opening 24 in each angled member 22. When each of the angled members 22 are adjacent to each other, the sizes of the second openings 24, together, are substantially equivalent to that of the first opening 12. Thus, when the apparatus is assembled, as shown in FIG. 2, the second openings 24 overlays the first opening 12.

Within each second opening 24 is either a solid EMI/RFI shielding member 26, or a modified EMI/RFI shielding member 28, which is designed to allow a cable 30 to pass through the member 28. The member 28 has a hole 32 that is specially designed to accommodate the thickness of the cable 30. The hole 32 in each member 28 can be a different size, to accommodate a different type of cable, so long as the cable is still surrounded at the point of entry by the EMI shielding material to effectively shield EMI within the system. The shielding material can be any material that is used to ground cables or shield interference from them. The preferred embodiment uses a silicone elastomer, with nickel-coated graphite filler material, namely the Instrument Specialties ElectroSeal Conductive Elastomer EMI Shielding, Material Number 12 manufactured by Laird Technologies. However, any other material or materials known to act as an Electrically Conductive Elastomer can be used. Once all of the shielding members 26 and 28 are loaded into the openings 24, the side brackets 18 are attached to the angled members 22, by screws 34. The screws 34 can be of any type of connector that is used to connect metal parts and is removable and replaceable. Next, the top bracket 14 and the bottom bracket 16 are attached. This entire structure is then attached to the front panel 10, so that the angled members are lined up properly with the opening 12 in the front panel 10. The cable 30 is then shielded from EMI as it enters the structure through the second opening 24 and the first opening 12, because it is surrounded at the entry point by the shielding member 28.

The shielding member 28 can be designed, or adapted, so that when the cable 30 passes through the shielding member 28, there is minimal gap between the cable 30 and the shielding member 28. This is important to ensure that EMI shielding and grounding is maintained. When assembled, the structure appears as in FIG. 2, with any number of cables 30, possibly of varying lengths and thicknesses, entering or exiting through the openings 24 surrounded by shielding members 28. When the larger structure, which the present embodiment is a part, requires an update to the cabling, the screws 34 can be removed. The particular shielding member 28 holding the cable 30 that requires replacing can itself be replaced by another shielding member 28 that can accommodate the thickness of the new cable 30 without significant air space. This ensures that the EMI shielding is maintained. The screws are then replaced, reattaching all of the component parts, to create the embodiment seen in FIG. 2, but with different cable 30 installed. Because of the modular nature of the present invention, this can be accomplished without shutting down the apparatus, or otherwise interrupting its operation. The present invention enables users of the device to upgrade cables easily and efficiently.

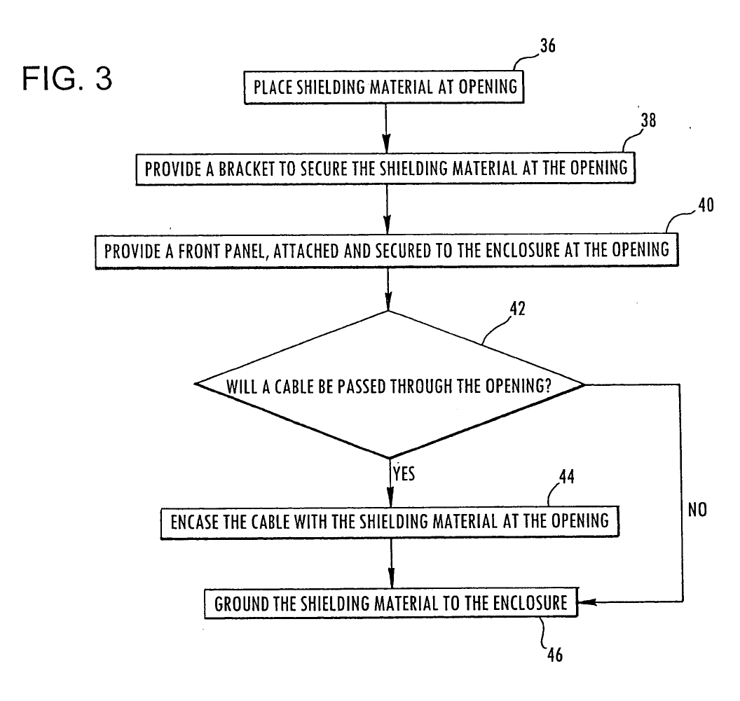

Referring now to FIG. 3, a method of limiting interference into and out of an enclosure is shown. The method can be used to limit interference in the enclosure caused by an opening in that enclosure. The method further ensures that the shielded faraday cage of the enclosure is maintained. The interference can be electromagnetic interference, radio frequency interference or any other interference caused by electric wires or cables. First, the step 36 of placing the shielding material at the opening is accomplished. The shielding material can be made from any material or combination of materials that act as an Electrically Conductive Elastomer. In the preferred embodiment, the shielding material is a silicone elastomer, with nickel-coated graphite filler material, namely the Instrument Specialties ElectroSeal Conductive Elastomer EMI Shielding, Material Number Twelve. In a preferred embodiment, the step 38 of providing a bracket is completed to ensure that the shielding material is secured to the enclosure at the opening. A panel is provided by another step 40. The panel is attached and secured to the enclosure at the opening. This front panel can be omitted, and the invention can retain all of its benefits. However, in the preferred embodiment, the front panel is provided, among other functions, to simplify securing of the shielding material, within the bracket, to the shielded enclosure. The next step 42 then determines if a cable is passed through the opening 32. If the answer is yes, then the step 44 of encasing the cable, at the opening, with the shielding material is completed. If a cable is not passed through the opening or if a cable is passed through the opening, the next step 46 in the process step 46 is to ground the shielding material to the enclosure.

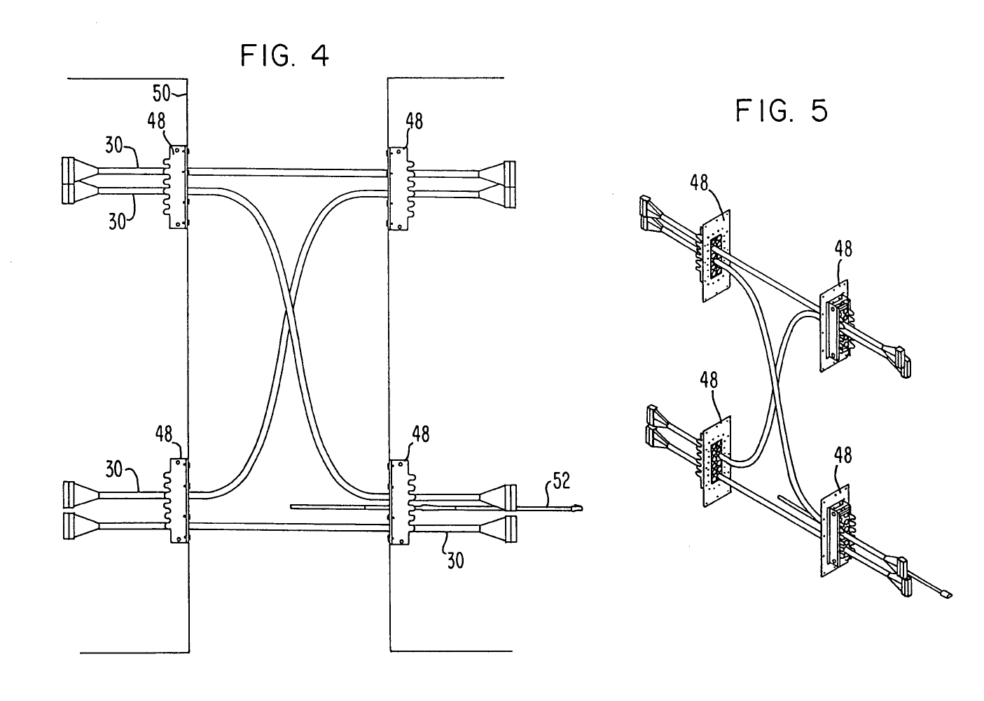

Referring now to FIG. 4, a plurality of clamping shielding apparatuses 48 are shown. In this embodiment of the present invention, the apparatuses 48 are the same as the apparatus depicted in detail in FIGS. 1 and 2. The apparatuses 48 are positioned in various places around the perimeter of an electronic cabinet system 50. A plurality of cables 30 enter through one of the apparatuses 48. The apparatus 48 contains a shielding member 28 (not shown in FIG. 4 or 5) that is designed to accommodate, either through special manufacture or through field adjustment, a opening having the exact thickness of the cable 30. When installing the system depicted in FIGS. 4 and 5, if a shielding member 28 cannot appropriately surround a cable having the thickness of the cable 30 within the apparatus 48, one can be cheaply purchased, and easily installed. The shielding material can be any material that is used to ground cables or shield interference from them. The preferred embodiment uses a silicone elastomer, with nickel-coated graphite filler material, namely the Instrument Specialties ElectroSeal Conductive Elastomer EMI Shielding, Material Number 12. However, any other material or materials known to act as an Electrically Conductive Elastomer can be used. The field upgrade process is described above, during the discussion of FIGS. 1 and 2. Once the apparatus 48 is properly configured to accept a cable the size of the cable 30, the cable then enters the cabinet 50 through the apparatus 48. The cable 30 then exits the cabinet 50 through another apparatus 48, which is also properly configured with shielding members 28 designed to accommodate, through adjustment or special manufacture, cables having the thickness of the cable 30. Because the cable 30 enters the cabinet through a shielded member 28, and exits through another shielded member 28, the faraday cage is maintained within the cabinet 50. Because the cabinet 50 is protected in this way, it can be used as a sub-chassis in a larger electronic system (not shown).

A second cable 52 is also shown. The second cable 52 has a different thickness than the first cable 30. Thus, it is shown that the present invention can accommodate cables having differing thicknesses, by simply having shielding members 28 designed to accommodate a cable with that particular thickness. If more cables having the thickness of cable 52 are later needed, either to replace the cable 30 or in addition to the existing cables 30 and 52, the filling member 28 constructed to accommodate cable 30, or the solid filling members 26, can be replaced with a filling member designed to accommodate cables having the thickness of cable 52, using the simple method described above, where the clamping brackets are loosened, the shielding members replaced, and the clamping brackets tightened. Thus, the apparatus depicted in FIGS. 4 and 5 can be used to shield interference while allowing multiple cables of varying thickness to enter and exit the shielded cabinet.

The above description and drawings are only illustrative of preferred embodiments which achieve the objects, features, and advantages of the present invention, and it is not intended that the present invention be limited thereto. Any modification of the present invention which comes within the spirit and scope of the following claims is considered to be part of the present invention.

What is claimed is:

1. An apparatus capable of reducing interference caused by an opening within an enclosure, comprising:
a first opening in said enclosure;
a first filling member, located within said opening, wherein said filling member shields said interference.

2. The apparatus of claim 1, further comprising a clamping bracket, positioned adjacent to said first opening, wherein said clamping bracket has a second opening positioned adjacent to said first opening.

3. The apparatus of claim 1, wherein a cable is positioned through an opening of said first filling member.

4. The apparatus of claim 3, wherein said first filling member is constructed from a non-radiating material.

5. The apparatus of claim 4, wherein said material comprises silicone and nickel coated graphite.

6. The apparatus of claim 5, wherein said first filling member does not contain an opening.

7. The apparatus of claim 3, wherein said clamping bracket can be opened and said first filling member can be replaced by a second filling member without significant disruption to the operation of said apparatus.

8. The apparatus of claim 7, wherein said second filling member has an opening having a different diameter from the opening in said first filling member.

9. The apparatus of claim 7, wherein said second filling member has no opening.

10. A method of limiting interference caused by an opening in an enclosure, comprising the steps of:
placing a shielding material at said opening;
encasing said cable with said shielding material at said opening; and
grounding said shielding material to said enclosure.

11. The method of claim 10, wherein said shielding material is comprised of silicon and nickel-coated graphite.

12. The method of claim 10, further comprising providing a bracket to secure said shielding material at said opening.

13. The method of claim 12, further comprising providing a front panel which is secured to said enclosure at said opening, said bracket is attached to said front panel.

14. The method of claim 12, wherein said bracket secures a plurality of said shielding material.

15. An system for limiting interference into and out of an enclosure, wherein said interference leaks through an opening of said enclosure, comprising:
means for shielding said interference at said opening; and
means for grounding shielding material to said enclosure.

16. The system as in claim 15, further comprising means for allowing an object to pass through said means for shielding.

17. The system as in claim 15, further comprising means for holding a plurality of said means for shielding.

18. The system as in claim 17, further comprising means for securing said means for holding to said enclosure.

19. An apparatus for reducing the introduction of interference into an enclosure caused by an opening in the enclosure opening, comprising:
shielding material located at said opening; and
a securing bracket that holds said shielding material at said enclosure opening.

20. The apparatus as in claim 19, further comprising a face plate with an opening.

21. The apparatus as in claim 19, wherein said bracket holds a plurality of said shielding material.

22. The apparatus as in claim 19, wherein said shielding material encases a cable passing through it.

23. The apparatus as in claim 19, wherein said shielding material does not contain a shielding opening.

24. The apparatus as in claim 22, wherein said shielding opening is equal to a diameter of the cable.

25. An apparatus comprising:
a cabinet having electrical components therein;
a first opening located on a first outer portion of said cabinet;
a second opening located on a second outer portion of said cabinet;
a first filling member, which shields interference, within said first opening and a second filling member, which shields interference, within said second opening.

26. The apparatus of claim 25, further comprising a first clamping bracket, positioned adjacent to said first opening, and a second clamping bracket, positioned adjacent to said second opening, wherein said first clamping bracket couples said first filling member to said cabinet at said first opening, and said second clamping bracket couples said second filling member to said cabinet at said second opening.

27. The apparatus of claim 25, further comprising a first cable, wherein said first cable enters said cabinet through said first opening, encased by said first filling member, and said cable exits said cabinet through said second opening, encased by said second filling member.

28. The apparatus of claim 26, wherein said first filling member can be replaced by a third filling member without significant disruption to the operation of said apparatus.
